(19) United States
(12) Patent Application Publication
(10) Pub. No.: US 2022/0310462 A1
(43) Pub. Date: Sep. 29, 2022

(54) SEMICONDUCTOR STRUCTURE

(71) Applicant: CHANGXIN MEMORY TECHNOLOGIES, INC., Hefei City, Anhui Province (CN)

(72) Inventor: ChihCheng LIU, Hefei (CN)

(73) Assignee: CHANGXIN MEMORY TECHNOLOGIES, INC., Hefei City, Anhui Province (CN)

(21) Appl. No.: 17/430,093

(22) PCT Filed: Mar. 18, 2021
(86) PCT No.: PCT/CN2021/081445

§ 371 Date: Aug. 11, 2021

(30) Foreign Application Priority Data
Mar. 25, 2020 (CN) 202010216439.3

(51) Int. Cl. H01L 21/66; H01L 23/00; H01L 23/58

(52) U.S. Cl. CPC H01L 22/34; H01L 23/562; H01L 23/585

(57) ABSTRACT

Disclosed is a semiconductor structure, disposed on a substrate surface of the die, and the die comprises an internal chip circuit. The semiconductor structure comprises: a first guard ring, annularly disposed around the internal chip circuit and configured to suppress a mechanical damage to the die; and a second guard ring, annularly disposed around the internal chip circuit and configured to suppress the mechanical damage and to monitor the magnitude of the mechanical damage. The second guard ring comprises a plurality of first structures and a plurality of second structures, and the first structure and the second structure have different mechanical strengths and different resistivities.

### CROSS-REFERENCE TO RELATED APPLICATIONS

The present application claims priority to Chinese Patent Application No. 2020102164393, entitled “SEMICONDUCTOR STRUCTURE” and filed with the China National Intellectual Property Administration on Mar. 25, 2020, the entire contents of which are incorporated herein by reference.

### TECHNICAL FIELD

The present invention relates to the field of semiconductors, in particular to a semiconductor structure.

### BACKGROUND

With the continuous development of semiconductor technologies, people's requirements for chip preparation technologies are also constantly increasing. At present, in a chip preparation process, the process flow of coating, developing, etching, doping, or the like is carried out on a wafer to form a die; then a pin test is performed on the die to confirm the device performance of the die; next, the die passing the pin test is diced and packaged; and finally the packaged chip is subjected to the final performance test.

However, when the wafer is diced and packaged, it is easy to cause mechanical damage to the die due to excessive dicing pressure of a dicing knife and excessive packaging pressure. Moreover, when the die has a mechanical damage and the mechanical damage is severe, a structure of an internal chip circuit will be damaged, resulting in partial or even complete failure of the device's functions; when the mechanical damage is small, on the other hand, water molecules and oxygen molecules will enter the internal chip circuit of the die from the position of the mechanical damage, thereby oxidizing or corroding metal wires in the internal chip circuit and further causing the internal chip circuit to fail.

### SUMMARY

According to various embodiments, a semiconductor structure is provided.

A semiconductor structure is disposed on a substrate surface of a die and the die includes an internal chip circuit. The semiconductor structure includes:

a first guard ring, disposed around the internal chip circuit and configured to suppress a mechanical damage to the die; and

a second guard ring, disposed around the internal chip circuit and configured to suppress the mechanical damage and to monitor a magnitude of the mechanical damage;

wherein the second guard ring includes a plurality of first structures and a plurality of second structures, and the first structure and the second structure have different mechanical strengths and different resistivities.

The above-mentioned semiconductor structure is disposed on the substrate surface of the die, and the die includes an internal chip circuit. The semiconductor structure includes: a first guard ring, annularly disposed around the internal chip circuit and configured to suppress a mechanical damage to the die; a second guard ring, annularly disposed around the internal chip circuit and configured to suppress the mechanical damage and to monitor the magnitude of the mechanical damage; wherein the second guard ring includes a plurality of first structures and a plurality of second structures, the first structure and the second structure have different mechanical strengths and different resistivities. Since the first guard ring and the second guard ring provide double protection for the internal chip circuit, the problem of insufficient resistance of a single guard ring to the deformation of the substrate is solved, and the mechanical damage to the die is effectively suppressed, thereby improving the reliability of the guard rings and the internal chip circuit; moreover, the mechanical damage condition of the die can be obtained in real time by monitoring the magnitude of the mechanical damage, so as to adjust the dicing and protection strategy of the die in time to improve a processing yield of the chip.

### BRIEF DESCRIPTION OF DRAWINGS

In order to better describe and illustrate embodiments of the present disclosure, reference may be made to one or more accompanying drawings. Additional details or examples used to describe the accompanying drawings should not be considered as limitations on the scope of any of the invention-creations, the embodiments described hereinafter, and the preferred embodiments of the present disclosure.

FIG. 1 is a schematic top view of a semiconductor structure according to an embodiment;

FIG. 2 is a schematic partial enlarged diagram of a crack in the embodiment of FIG. 1;

FIG. 3 is a schematic top view of a semiconductor structure according to another embodiment;

FIG. 4 is a schematic top view of a first guard ring according to an embodiment;

FIG. 5 is a schematic top view of a second guard ring according to an embodiment;

FIG. 6 is a schematic cross-sectional view of the second guard ring 200 in the embodiment of FIG. 5 along the A-A direction;

FIG. 7 is a schematic cross-sectional view of the second guard ring 200 in the embodiment of FIG. 5 along the B-B direction;

FIG. 8 is a schematic top view of a second guard ring provided with two openings according to an embodiment;

FIG. 9 is a schematic cross-sectional view of a conductor structure according to an embodiment;

FIG. 10 is a schematic cross-sectional view of a conductor structure according to another embodiment;

FIG. 11 is a schematic cross-sectional view of a through hole of a groove structure according to an embodiment;

FIG. 12 is a schematic partial cross-sectional view of a second guard ring according to an embodiment;

FIG. 13 is a schematic cross-sectional view of a first structure of the embodiment in FIG. 12;

FIG. 14 is a schematic cross-sectional view of a second structure of the embodiment in FIG. 12;

FIG. 15 is a flowchart of a preparation method of a semiconductor structure according to an embodiment; and

FIG. 16 is a sub-flow chart of step S300 in an embodiment.

### DESCRIPTION OF EMBODIMENTS

For easy understanding of the present disclosure, a more comprehensive description of the present disclosure will be given below with reference to the relevant accompanying drawings. Preferred embodiments of the present disclosure are given in the drawings. However, the present disclosure may be implemented in many different forms and is not limited to the embodiments described herein. Rather, these embodiments are provided to make the contents disclosed in the present disclosure more thorough and comprehensive.

Unless defined otherwise, all technical and scientific terms used herein have the same meanings as are commonly understood by those skilled in the art. The terms used herein in the specification of the present disclosure are for the purpose of describing specific embodiments only but not intended to limit the present disclosure. The term “and/or” used herein includes any and all combinations of one or more related listed items.

In the description of the present disclosure, it should be understood that the orientation or position relationship indicated by the terms “upper”, “lower”, “vertical”, “horizontal”, “inner”, “outer”, or the like are based on the orientation or position relationship shown in the accompanying drawings and are intended to facilitate the description of the present disclosure and simplify the description only, rather than indicating or implying that the apparatus or element referred to must have a particular orientation or be constructed and operated in a particular orientation, and therefore are not to be interpreted as limiting the present disclosure.

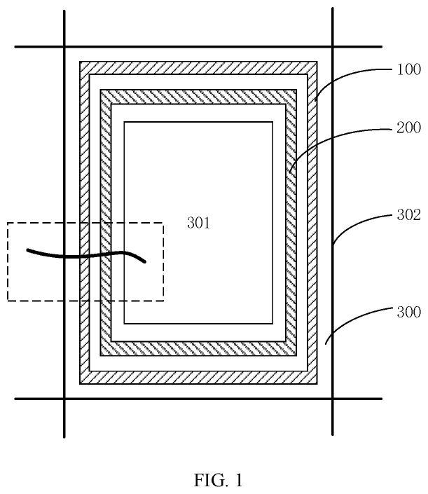

FIG. 1 is a schematic top view of a semiconductor structure according to an embodiment. As shown in FIG. 1, the semiconductor structure is disposed on a substrate surface of a die 300, the die 300 includes an internal chip circuit 301, and the semiconductor structure includes a first guard ring 100 and a second guard ring 200.

The first guard ring 100 is annularly disposed around the internal chip circuit 301 and configured to suppress a mechanical damage to the die 300.

The mechanical damage of the die 300 refers to a crack caused by a deformation of the substrate of the die 300. The temperature and humidity changes in the environment where the die 300 is located, as well as the dicing and packaging processes all have the risk of causing the mechanical damage.

Specifically, the first guard ring 100 is disposed between the internal chip circuit 301 and a dicing lane 302. The first guard ring 100 is of a closed ring structure and has a large ring width and a high mechanical strength. The first guard ring 100, on the one hand, can eliminate an internal stress of the die 300 caused by the dicing and packaging process, thereby reducing the probability of the mechanical damage to the die 300; on the other hand, when the die 300 is mechanically damaged, the high mechanical strength of the first guard ring 100 can suppress the further spread and development of the mechanical damage. Moreover, after the die 300 is packaged, the first guard ring 100 can also prevent the intrusion of external water molecules and oxygen molecules, thereby avoiding oxidation or corrosion of the metal lines of the internal chip circuit, and improving the reliability and stability of the packaged chip.

The second guard ring 200 is annularly disposed around the internal chip circuit 301 and configured to suppress the mechanical damage and to monitor the magnitude of the mechanical damage.

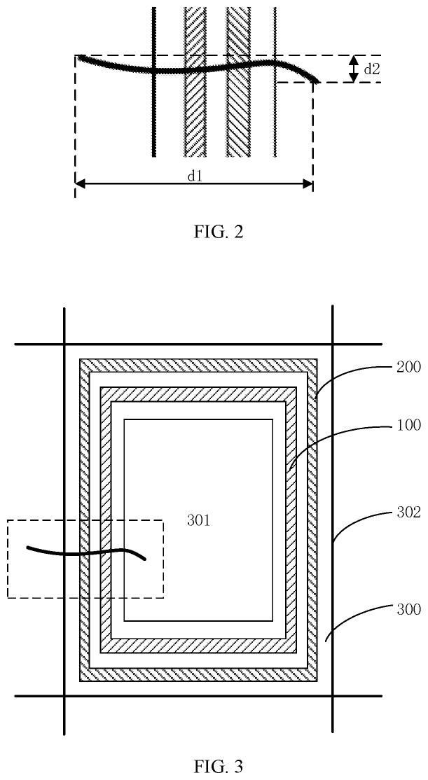

The magnitude of the mechanical damage includes the length and width of the crack. FIG. 2 is a schematic partial enlarged diagram of the crack in the embodiment of FIG. 1. As shown in FIG. 2, the length of the crack refers to the dimension d1 of the crack in the X direction, and the width of the crack refers to the dimension d2 of the crack in the Y direction.

Specifically, the second guard ring 200 is also disposed between the internal chip circuit 301 and the dicing lane 302, wherein the second guard ring 200 includes a plurality of first structures and a plurality of second structures, and the first structure and the second structure have different mechanical strengths and different resistivities. The part with a high mechanical strength in the second guard ring 200 has a stronger ability to resist the internal stress and is configured to suppress the mechanical damage; when the mechanical damage to the second guard ring 200 causes the change in the resistance value of the internal structure, the resistance value of the part with a high resistivity changes more than that of the part with a low resistivity. Therefore, the part with a high resistivity can more accurately reflect the magnitude of the mechanical damage, so as to realize real-time monitoring to the mechanical damage.

The above-mentioned semiconductor structure is disposed on a substrate surface of the die 300, and the die 300 includes an internal chip circuit 301. The semiconductor structure includes: a first guard ring 100, annularly disposed around the internal chip circuit 301 and configured to suppress the mechanical damage of the die 300; and a second guard ring 200, annularly disposed around the internal chip circuit 301 and configured to suppress the mechanical damage and to monitor the magnitude of the mechanical damage; wherein the second guard ring 200 includes a plurality of first structures and a plurality of second structures, and the first structure and the second structure have different mechanical strengths and different resistivities. Since the first guard ring 100 and the second guard ring 200 provide double protection for the internal chip circuit 301, the problem of insufficient resistance of a single guard ring to the deformation of the substrate is solved, and the mechanical damage to the die 300 is effectively suppressed, thereby improving the reliability of the guard rings and the internal chip circuit 301; moreover, the mechanical damage condition of the die 300 can be obtained in real time by monitoring the magnitude of the mechanical damage, so that the dicing and protection strategies of the die 300 can be adjusted in time to improve the processing yield of the chip.

It should be noted that projections of the first guard ring 100 and the second guard ring 200 on the substrate do not overlap with each other. As shown in FIG. 1, the first guard ring 100 is disposed between the second guard ring 200 and the dicing lane 302, and the second guard ring 200 is disposed between the internal chip circuit 301 and the first guard ring 100. A schematic top view of the semiconductor structure of another embodiment is shown in FIG. 3, where the first guard ring 100 is disposed between the internal chip circuit 301 and the second guard ring 200, and the second guard ring 200 is disposed between the first guard ring 100 and the dicing lane 302. The two embodiments of FIG. 1 and FIG. 3 can both achieve the purpose of suppressing the mechanical damage and monitoring the magnitude of the mechanical damage.

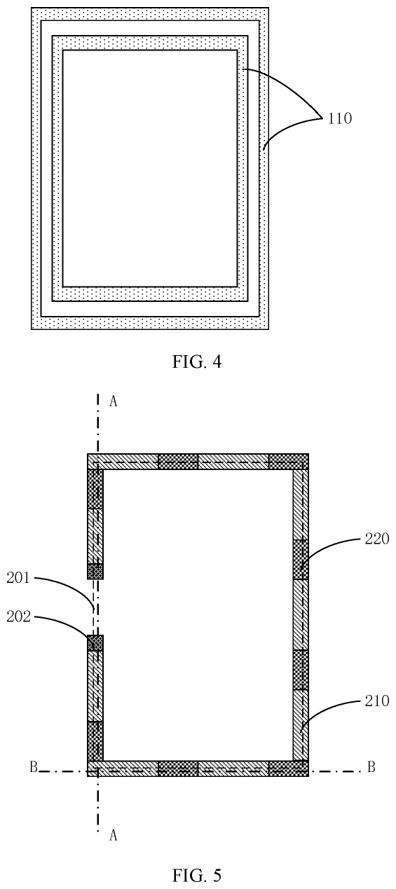

FIG. 4 is a schematic top view of the first guard ring 100 according to an embodiment. As shown in FIG. 4, the first guard ring 100 includes two sub guard rings 110, the two sub guard rings 110 are annularly disposed in a radial direction and spaced apart. The two sub guard rings 110 work together to suppress the mechanical damage. Ring widths of the two sub guard rings 110 may be the same, for example, the ring widths of the two sub guard rings 110 are both 2 um; the ring widths of the two sub guard rings 110 may also be different, for example, the ring width of the sub guard ring 110 located on an outer side is 2.5 um, and the ring width of the sub guard ring 110 located on an inner side is 1.5 um.

Further, the first guard ring 100 may also include a plurality of sub guard rings 110. Specifically, when the size of the die 300 is large, for example, 100 mm², the die 300 is more prone to a mechanical damage, so three sub guard rings 110 can be disposed to provide better protection for the internal chip circuit; when the size of the die 300 is small, for example, 10 mm², the die 300 is not prone to a mechanical damage, so only two sub guard rings 110 can be disposed, thereby reducing an occupied area of the first guard ring 100 on the substrate surface.

In an embodiment, the first guard ring 100 is disposed in contact with a surface of an active region of the substrate, and the active region may be N-type or P-type.

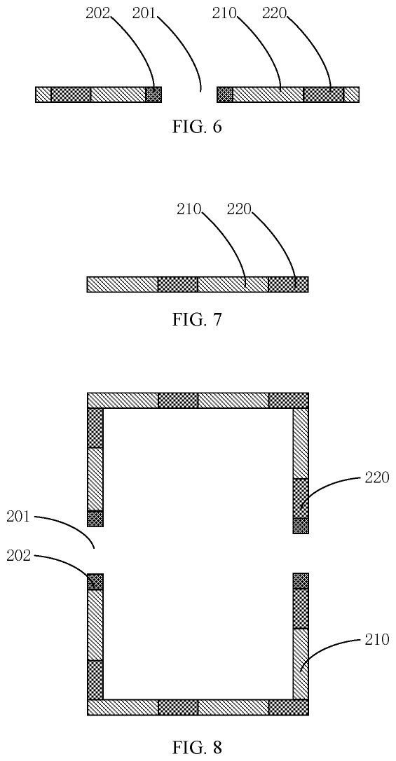

FIG. 5 is a schematic top view of the second guard ring 200 according to an embodiment. FIG. 6 is a schematic cross-sectional view of the second guard ring 200 in the embodiment of FIG. 5 along the A-A direction. FIG. 7 is a schematic cross-sectional view of the second guard ring 200 in the embodiment of FIG. 5 along the B-B direction. As shown in FIGS. 5 to 7, in this embodiment, the projections of the first structure 210 and the second structure 220 on the substrate do not overlap, and the first structure 210 and the second structure 220 are spaced apart from each other on an extension path of the second guard ring 200.

Specifically, a rectangular path drawn by the dashed line in FIG. 5 is the extension path of the second guard ring 200. The expression that the first structure 210 and the second structure 220 are spaced apart from each other means that there must be a second structure 220 disposed adjacent to each first structure 210 and there must be a first structure 210 disposed adjacent to each second structure 220. In this embodiment, due to the first structure 210 and the second structure 220 spaced apart, the die 300 can be protected evenly in all directions, thereby preventing the die 300 from a mechanical damage due to an excessive stress in a certain direction on the one hand; on the other hand, resistance changes in various directions can be simultaneously acquired to monitor mechanical damages in different directions, so that the dicing and protection strategies of the die 300 can be flexibly monitored and adjusted accordingly. It should be noted that the cross-sectional schematic diagrams in the following embodiments are all cross-sectional schematic diagrams along the B-B direction, and will not be repeated in the following embodiments.

In an embodiment, the mechanical strength of the first structure 210 is greater than the mechanical strength of the second structure 220, and the first structure 210 is configured to suppress the mechanical damage. It can be understood that the mechanical strength of a structure is determined by the characteristics of its material itself and the composition characteristics of the structure. Therefore, the first structure 210 can be made of a material with a high shear resistance coefficient and a high tensile strength coefficient to improve the mechanical strength of the first structure 210; the first structure 210 with a large cross-sectional area may also be formed to improve the mechanical strength of the first structure 210.

In an embodiment, the resistivity of the second structure 220 is greater than the resistivity of the first structure 210, and the resistance value of the second structure 220 matches the magnitude of the mechanical damage. It can be understood that the resistivity of a structure is determined by the characteristics of its material itself and the composition characteristics of the structure, or the like Therefore, the second structure 220 can be made of a material with a high resistivity to increase the resistivity of the second structure 220; the second structure 220 with a small cross-sectional area or a long length may also be formed to improve the resistivity of the second structure 220. The expression that the resistance value of the second structure 220 matches the magnitude of the mechanical damage means that the resistance value of the second structure 220 has a correlation with the magnitude of the mechanical damage. Specifically, the correlation may be a positive correlation, that is, the larger the width and/or the length of the crack, the higher the resistance value of the second structure 220; the correlation may also be a negative correlation, that is, the larger the width and/or the length of the crack, the lower the resistance value of the second structure 220.

In an embodiment, as shown in FIGS. 5 to 7, the second guard ring 200 is a non-closed ring, the second guard ring 200 is provided with an opening 201, and lead-out terminals 202 are disposed at the opening 201; the lead-out terminals 202 are connected to a monitoring module to obtain the resistance information of the second guard ring 200. The resistance information here can be the resistance value, such as 5 Q and 10 Q; it can also be the resistance change value, i.e., the difference between the resistance value at the current test time and the resistance value at the previous test time, such as 0.5 Q and 0.1 Q; it can also be the resistance change rate, i.e., the ratio of the difference between the resistance value at the current test time and the resistance value at the previous test time to the test time interval, such as 0.005 Q/ms and 0.01 Q/ms. When a resistance change rate has a sudden change, it indicates that the magnitude of the mechanical damage has changed suddenly, and therefore, the change in the mechanical damage can be obtained more accurately and quickly.

Further, the monitoring module has a monitoring function and a warning function. The monitoring function is used to obtain the resistance information of the second guard ring 200 in real time, and the warning function is used to send a warning signal according to a preset warning condition and the resistance information. For example, the preset warning condition is that the real-time resistance value exceeds a resistance threshold. When the real-time resistance value is less than the resistance threshold, no warning signal will be sent; when the real-time resistance value is not less than the resistance threshold, a warning signal will be sent to remind an operator, a dicing device or a packaging device to adjust the die dicing and protection strategies.

In an example, the monitoring module is an external resistance test device. When the external resistance test device is used to monitor the second guard ring 200, a test probe of the resistance test device is connected to the lead-out terminals 202 to obtain the resistance information of the second guard ring 200. The external resistance test device can be compatible with a larger data storage space, and save resistance information in the data storage space for a large time range, so that more reference data can be provided for dicing and packaging process control over other dies.

In another example, the monitoring module is a monitoring circuit disposed on the substrate surface. Further, the monitoring circuit can be integrated in the internal chip circuit 301, or can be independently disposed outside the internal chip circuit 301. The monitoring circuit disposed on the substrate surface is not limited by the test location and the external test device, so the resistance information of the second guard ring 200 can be monitored more flexibly.

In the embodiment shown in FIGS. 5 to 7, the second guard ring 200 is provided with an opening 201, and two lead-out terminals 202 are disposed at the opening 201. The two lead-out terminals 202 can both be connected to the first structures 210; or both can be connected to the second structures 220; it is also possible that one lead-out terminal 202 is connected to a first structure 210, and the other lead-out terminal 202 is connected to a second structure 220. It should be noted that the “connected” in the expression “connected to the first structures 210 or the second structures 220” can be implemented by using one of the functional layers in the first structure 210 or the second structure 220 as the lead-out terminal 202 or arranging an additional lead-out terminal 202 and connecting the lead-out terminals 202 to the first structures 210 or the second structures 220 through metal wires.

FIG. 8 is a schematic top view of a second guard ring 200 provided with two openings 201 according to an embodiment. As shown in FIG. 8, the second guard ring 200 is provided with two openings 201, and two lead-out terminals 202 are disposed at each opening 201; the second guard ring 200 is divided into two guard segments by the two openings 201, and each pair of lead-out terminals 202 is configured to obtain the resistance information of the corresponding guard segment. In this embodiment, through the structure of two pairs of lead-out terminals 202 and two guard segments, the position and direction of the crack can be obtained more accurately.

In other embodiments, the second guard ring 200 may also be provided with a plurality of openings 201, two lead-out terminals 202 are disposed at each opening 201, and the second guard ring 200 is divided into a plurality of guard segments by the plurality of openings 201. Further, a plurality of guard segments can be disposed in areas prone to mechanical damage, such as the corner areas of the die 300, and one guard segment can be disposed in an area not prone to mechanical damage, such as a straight edge of the die 300, so as to monitor the mechanical damage more accurately.

In an embodiment, both the first structure 210 and the second structure 220 are laminated structures and include the same conductor structure. The same conductor structure refers to such a conductor structure that an arrangement order and material of all the functional layers in the device are the same, but the same conductor structure does not limit the specific sizes of the first structure 210 and the second structure 220, that is, the conductor structure of the first structure 210 and the second structure 220 may be different in size.

In an embodiment, each conductor structure includes: at least two metal layers; and a through hole layer disposed between the two adjacent metal layers and configured to connect the adjacent metal layers. Specifically, the two adjacent metal layers at least partially overlap in the vertical direction, and the through hole layer is disposed at an overlapped portion to conduct the adjacent metal layers.

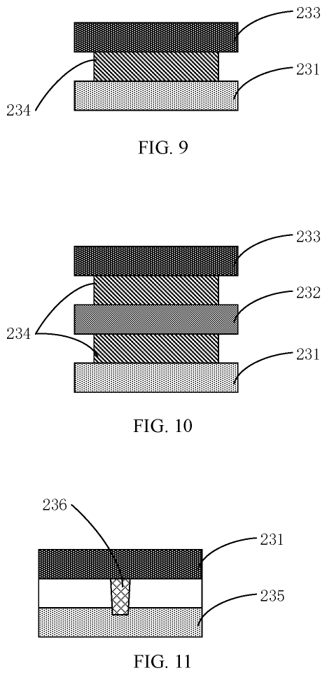

FIG. 9 is a schematic cross-sectional view of a conductor structure according to an embodiment. As shown in FIG. 9, the conductor structure includes two metal layers which are a top metal layer 233 and a bottom metal layer 231, and a through hole layer 234 is disposed between the top metal layer 233 and the bottom metal layer 231 to conduct the metal layers. FIG. 10 is a schematic cross-sectional view of a conductor structure according to another embodiment. As shown in FIG. 10, the conductor structure includes three metal layers, which are a top metal layer 233, a middle metal layer 232, and a bottom metal layer 231; a through hole layer 234 is disposed between the top metal layer 233 and the middle metal layer 232 to conduct the metal layers, and another through hole layer 234 is disposed between the middle metal layer 232 and the bottom metal layer 231 to conduct the metal layers. In other embodiments, the conductor structure may include at least four metal layers, which are a top metal layer 233, at least two middle metal layers 232, and a top metal layer 233, and a through hole layer 234 is disposed between every two adjacent metal layers to conduct the metal layers.

In one embodiment, as shown in FIG. 11 are a dielectric material and at least one through hole 236 formed in the dielectric material, wherein the through hole 236 penetrates the dielectric material in a vertical direction to conduct two adjacent conductive layers; the dielectric material is configured to maintain the structural stability of the through hole 236 to improve the mechanical strength of the first structure 210 and the second structure 220. Optionally, the dielectric material may be silicon oxide, silicon nitride, or silicon oxynitride, and is formed by ALD (Atomic Layer Deposition) or CVD (Chemical Vapor Deposition), so as to ensure the thickness accuracy of the through hole 236 and the film flatness.

In an embodiment, the through hole 236 may be of a groove structure. FIG. 11 is a schematic cross-sectional view of the through hole 236 of a groove structure according to this embodiment. As shown in FIG. 11, the conductive structure of this embodiment includes two conductive layers, and the through hole 236 of a groove structure refers to a through hole 236 formed by forming a groove with a set depth in the surface of the conductive layer 235 to be connected and filling the groove with a conductive material, so as to be electrically connected with the bottom metal layer 231, wherein the conductive layers 235 can be active regions or polysilicon. In this embodiment, the through hole 236 of a groove structure can ensure a large contact area between the through hole 236 and the conductive layer 235, thereby reducing the contact resistance.

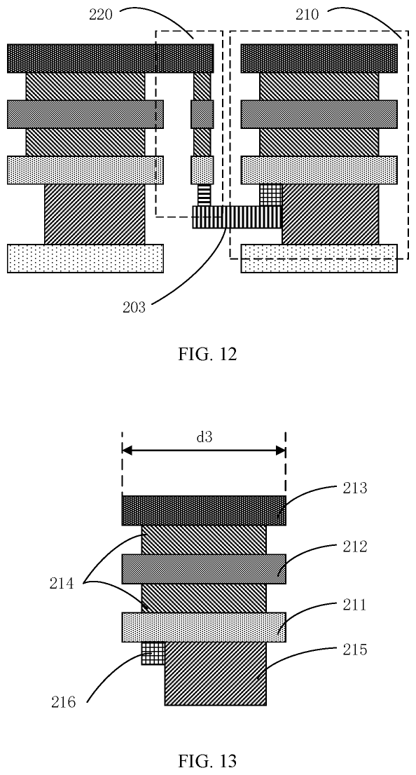

FIG. 12 is a schematic partial cross-sectional view of a second guard ring 200 according to an embodiment. In FIG. 12, only two first structures 210 and one second structure 220 are shown, and FIG. 12 is provided to show the connection relationship between the first structure 210 and the second structure 220. It should be noted that the connection relationship between the other unshown first structure 210 and the second structure 220 is the same as the connection relationship shown in FIG. 12.

FIG. 13 is a schematic cross-sectional view of a first structure 210 in the embodiment of FIG. 12. As shown in FIG. 13, the first structure 210 includes: a first conductive structure; a substrate contact hole 215 for connecting a first bottom metal layer 211 and an active region in the substrate; and a first conductor contact hole 216 for connecting the first bottom metal layer 211 and a conductor layer 203.

The first conductive structure includes the first bottom metal layer 211, a first middle metal layer 212, a first top metal layer 213, as well as first through hole layers 214 disposed between two adjacent metal layers, wherein the first bottom metal layer 211, the first middle metal layer 212, and the first top metal layer 213 are laminated in sequence. The first top metal layer 211 and the first middle metal layer 212 may be made of one of aluminum and copper, the first bottom metal layer 211 may be made of one of tungsten, aluminum, and copper, and the conductor layer 203 may be made of polysilicon.

FIG. 14 is a schematic cross-sectional view of a second structure 220 in the embodiment of FIG. 12. As shown in FIG. 14, the second structure 220 includes: a second conductive structure; and a second conductor contact hole 225 for connecting a second bottom metal layer 221 and the conductor layer 203; the second conductive structure includes a second bottom metal layer 221, a second middle metal layer 222, and a second top metal layer 223, as well as second through hole layers 224 disposed between two adjacent metal layers, wherein the second bottom metal layer 221, the second middle metal layer 222, and the second top metal layer 223 are laminated in sequence; the second conductive structure is the same as the first conductive structure, and the second top metal layer 223 is connected to the first top metal layer 213.

In this embodiment, through the above-mentioned first structure 210 and second structure 220, the second guard ring 200 with a high mechanical strength and accurate mechanical damage monitoring is realized. It should be noted that the two first top metal layers 213 can be used as lead-out terminals 202 connected to the monitoring module, or the two first bottom metal layers 211 can also be used as lead-out terminals 202 connected to the monitoring module. The positions of the lead-out terminals 202 in the first structures 210 and the second structures 220 are not specifically defined in this embodiment. The above-mentioned arrangements of the lead-out terminals 202 can both accurately monitor the mechanical damage of the die 300.

In an embodiment, as shown in FIGS. 13 to 14, the width d3 of the cross-section of the first structure 210 longitudinally cut along the extension path of the second guard ring 200 may be 5 um to 50 um, and the width d4 of the cross-section of the second structure 220 longitudinally cut along the extension path of the second guard ring 200 may be 0.5 um to lum.

It should be noted that the above specific numerical values are only for illustration, and do not constitute a limitation on the semiconductor structure involved in the present disclosure.

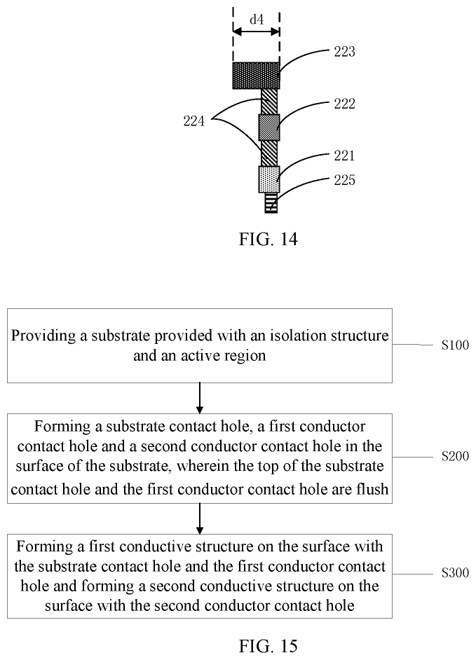

FIG. 15 is a flowchart of a preparation method of a semiconductor structure according to an embodiment. As shown in FIG. 15, the preparation method includes steps S100 to S300.

S100: providing a substrate provided with an isolation structure and an active region;

S200: forming a substrate contact hole 215, a first conductor contact hole 216 and a second conductor contact hole 225 in the surface of the substrate, wherein the top of the substrate contact hole 215 and the first conductor contact hole 216 are flush; and

S300: forming a first conductive structure on the surface with the substrate contact hole 215 and the first conductor contact hole 216, and forming a second conductive structure on the surface with the second conductor contact hole 225.

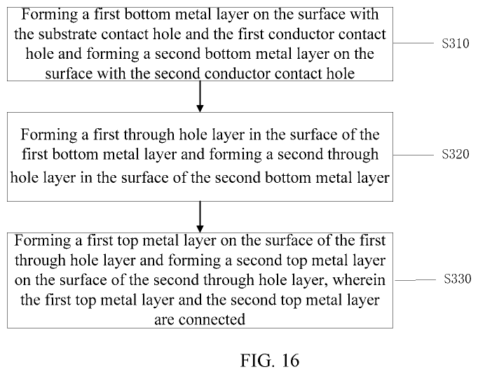

In an embodiment, both the first conductive structure and the second conductive structure include two metal layers, that is, the first conductive structure includes a first bottom metal layer 211 and a first top metal layer 213, and the second conductive structure includes a second bottom metal layer 221 and a second top metal layer 223. FIG. 16 is a sub-flow chart of step S300 in this embodiment. As shown in FIG. 16, step S300 includes steps S310 to S330.

S310: forming a first bottom metal layer 211 on the surface with the substrate contact hole 215 and the first conductor contact hole 216 and forming a second bottom metal layer 221 on the surface with the second conductor contact hole 225;

S320: forming a first through hole layer 214 in the surface of the first bottom metal layer 211 and forming a second through hole layer 224 in the surface of the second bottom metal layer 221; and

S330: forming a first top metal layer 213 on the surface of the first through hole layer 214 and forming a second top metal layer 223 on the surface of the second through hole layer 224, wherein the first top metal layer 213 is connected with the second top metal layer 223.

It should be understood that although the various steps in the flowcharts of FIGS. 15 to 16 are displayed in sequence as indicated by the arrows, these steps are not necessarily performed in sequence in the order indicated by the arrows. Unless there is a clear description herein, there is no strict limitation on the execution order of these steps, and these steps can be executed in other orders. Moreover, at least part of the steps in FIGS. 15 to 16 may include multiple sub-steps or multiple stages. These sub-steps or stages are not necessarily executed at the same time, but can be executed at different times. These sub-steps or stages are not necessarily performed in sequence, but may be performed in turn or alternately with other steps or at least a part of the sub-steps or stages of other steps.

Technical features of the above embodiments may be combined randomly. To make descriptions brief, not all possible combinations of the technical features in the embodiments are described. Therefore, as long as there is no contradiction between the combinations of the technical features, they should all be considered as scopes disclosed in the specification.

The above embodiments only describe several implementations of the present disclosure, and their description is specific and detailed, but cannot therefore be understood as a limitation on the patent scope of the present disclosure. It should be noted that those of ordinary skill in the art may further make variations and improvements without departing from the conception of the present disclosure, and these all fall within the protection scope of the present disclosure. Therefore, the patent protection scope of the present disclosure should be subject to the appended claims.

1. A semiconductor structure, disposed on a substrate surface of a die, the die comprising an internal chip circuit, wherein the semiconductor structure comprises:
a first guard ring, disposed around the internal chip circuit and configured to suppress a mechanical damage to the die; and
a second guard ring, disposed around the internal chip circuit and configured to suppress the mechanical damage and to monitor the magnitude of the mechanical damage;
wherein the second guard ring comprises a plurality of first structures and a plurality of second structures, and the first structure and the second structure have different mechanical strengths and different resistivities.

2. The semiconductor structure according to claim 1, wherein the first structure and the second structure are spaced apart from each other on an extension path of the second guard ring.

3. The semiconductor structure according to claim 1, wherein a mechanical strength of the first structure is greater than a mechanical strength of the second structure, and the first structure is configured to suppress the mechanical damage.

4. The semiconductor structure according to claim 1, wherein a resistivity of the second structure is greater than a resistivity of the first structure, and a resistance value of the second structure 220 matches the magnitude of the mechanical damage.

5. The semiconductor structure according to claim 1, wherein the second guard ring is provided with an opening, and lead-out terminals are disposed at the opening; the lead-out terminals are connected to a monitoring module to obtain the resistance information of the second guard ring.

6. The semiconductor structure according to claim 5, wherein the monitoring module is a monitoring circuit disposed on the substrate surface to obtain the resistance information of the second guard ring.

7. The semiconductor structure according to claim 1, wherein projections of the first structure and the second structure on the substrate do not overlap.

8. The semiconductor structure according to claim 1, wherein both the first structure and the second structure are laminated structures and comprise the same conductor structure.

9. The semiconductor structure according to claim 8, wherein each of the conductor structures comprises:
at least two metal layers; and
a through hole layer disposed between the two adjacent metal layers and configured to connect the adjacent metal layers.

10. The semiconductor structure according to claim 9, wherein each of the first structures comprises a substrate contact structure by which the conductor structure is electrically connected with the substrate.
